(19) United States
(12) Patent Application Publication
(10) Pub. No.: US 2022/0260355 A1
(43) Pub. Date: Aug. 18, 2022

(54) ROTOR APPARATUS AND APPARATUS FOR DETECTING ANGULAR POSITION OF ROTOR

(71) Applicant: SAMSUNG ELECTRO-MECHANICS CO., LTD., Suwon-si (KR)

(72) Inventor: Bon Young KOO, Suwon-si (KR)

(73) Assignee: SAMSUNG ELECTRO-MECHANICS CO., LTD., Suwon-si (KR)

(21) Appl. No.: 17/349,075

(22) Filed: Jun. 16, 2021

(30) Foreign Application Priority Data
Feb. 17, 2021 (KR) 10-2021-0020930

(51) Int. Cl. G01B 7/30; G01D 5/20

(52) U.S. Cl. CPC G01B 7/30; G01D 5/20

(57) ABSTRACT

A rotor apparatus includes: a rotor rotatable around a rotational axis; an angular position identification layer disposed to surround the rotational axis and configured to rotate according to rotation of the rotor, and having a width varying with angular positions of the rotor; and an angular range identification layer disposed to surround the rotational axis, configured to rotate according to the rotation of the rotor, having a shape different from a shape of the angular position identification layer, and configured such that an overall width of a portion of the angular range identification layer corresponding to an angular position range, among a plurality of different angular position ranges of the rotor, in which an angular position corresponding to a point having the largest change in width of the angular position identification layer is located, is different from an overall width of a remaining portion of the angular range identification layer.

### CROSS-REFERENCE TO RELATED APPLICATIONS

This application claims the benefit under 35 U.S.C. § 119(a) of Korean Patent Application No. 10-2021-0020930 filed on Feb. 17, 2021 in the Korean Intellectual Property Office, the entire disclosure of which is incorporated herein by reference for all purposes.

### BACKGROUND

### 1. Field

The following description relates to a rotor apparatus and an apparatus for detecting an angular position of a rotor.

### 2. Description of Related Art

Recently, types and designs of electronic devices have been diversified. User demands for electronic devices have also diversified, and a variety of requirements have been suggested for functions and designs of electronic devices.

Accordingly, an electronic device may include a rotor configured to perform various functions demanded by users, through efficient movement and design of the rotor.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a rotor apparatus includes: a rotor configured to rotate around a rotational axis; an angular position identification layer disposed to surround the rotational axis and configured to rotate according to rotation of the rotor, and having a width varying with angular positions of the rotor; and an angular range identification layer disposed to surround the rotational axis, configured to rotate according to the rotation of the rotor, having a shape different from a shape of the angular position identification layer, and configured such that an overall width of a portion of the angular range identification layer corresponding to an angular position range, among a plurality of different angular position ranges of the rotor, in which an angular position corresponding to a point having the largest change in width of the angular position identification layer is located, is different from an overall width of a remaining portion of the angular range identification layer.

The angular position identification layer and the angular range identification layer may include any one or any combination of any two or more of copper, silver, gold, or aluminum as a material, different from a material of the rotor, respectively.

The angular range identification layer may have a width changing in a highest ratio in a portion corresponding to both sides of an angular position range, among the plurality of different angular position ranges, to which the angular position corresponding to the point having the largest change in width of the angular position identification layer belongs.

A widest portion of the angular range identification layer may have a constant width between points of the angular range identification layer having the largest change in width.

The angular position identification layer may have a width changing linearly, except for the point having the largest change in width.

A change in width of a plurality of points having the largest change in width in the angular range identification layer may be greater than a change in width of a portion of the angular range identification layer in which a width changes linearly, except for the point having the largest change in width in the angular position identification layer.

The angular position identification layer may have a width corresponding one-on-one to an angular position in one turn range of the rotor.

A clockwise length and a counterclockwise length between a point having a maximum width and a point having a minimum width in the angular position identification layer may be different from each other.

A clockwise length and a counterclockwise length between one point and another point among a plurality of points having the largest change in width in the angular range identification layer may be different from each other.

In another general aspect, a rotor apparatus includes: a rotor configured to rotate around a rotational axis; an angular position identification layer disposed to surround the rotational axis and configured to rotate according to rotation of the rotor, and having a width varying with angular positions of the rotor; and an angular range identification layer disposed to surround the rotational axis, configured to rotate according to the rotation of the rotor, having a shape different from a shape of the angular position identification layer, and configured such that an overall width of a portion of the angular range identification layer corresponding to an angular position range, among a plurality of different angular position ranges of the rotor, in which an angular position corresponding to a point reversing a width change direction of the angular position identification layer is located, is different from an overall width of a remaining portion of the angular range identification layer.

A clockwise length and a counterclockwise length between a point having a maximum width and a point having a minimum width in the angular position identification layer may be different from each other.

A clockwise length and a counterclockwise length between a plurality of points having the largest change in width in the angular range identification layer may be different from each other.

A widest portion of the angular range identification layer may have a constant width between points of the angular range identification layer having the largest change in width.

The angular position identification layer may have a width changing linearly.

In another general aspect an apparatus for detecting an angular position of a rotor includes: an angular position identification inductor; an angular range identification inductor; a rotor configured to rotate around a rotational axis; an angular position identification layer disposed to surround the rotational axis and configured to rotate according to rotation of the rotor, and configured to change an inductance of the angular position identification inductor according to angular positions of the rotor; and an angular range identification layer disposed to surround the rotational axis and configured to rotate according to the rotation of the rotor, and configured such that overall inductance of the angular range identification inductor in an angular position range, among a plurality of different angular position ranges of the rotor, in which an angular position corresponding to a point reversing an inductance change direction of the angular position identification inductor is located, is different from overall inductance of the angular range identification inductor in a remaining angular position range among the plurality of different angular position ranges.

The apparatus may further include a processor configured to generate an angular position value, based on one operation logic selected based on the inductance of the angular range identification inductor, among a plurality of operation logics, and based on the inductance of the angular position identification inductor.

The processor may be further configured to correct the angular position value or the inductance of the angular position identification inductor, based on the inductance of the angular range identification inductor.

The apparatus may further include a processor configured to generate an angular position value, based on a look-up table selected based on the inductance of the angular range identification inductor or determined whether to be used according to the inductance of the angular range identification inductor and the inductance of the angular position identification inductor.

The apparatus may further include a processor configured to generate an angular position value based on the inductance of the angular position identification inductor, and correct the angular position value based on the inductance of the angular range identification inductor.

The apparatus may further include a processor configured to generate an angular position value corrected from the inductance of the angular position identification inductor, based on one correction logic selected based on the inductance of the angular range identification inductor, among a plurality of correction logics.

Other features and aspects will be apparent from the following detailed description, the drawings, and the claims.

### BRIEF DESCRIPTION OF DRAWINGS

FIG. 1 is an exploded view illustrating a detailed form of a rotor apparatus and an apparatus for detecting an angular position of a rotor, according to an embodiment.

FIGS. 2A and 2B are perspective views illustrating apparatuses for detecting an angular position of a rotor, according to embodiments.

FIGS. 3A to 3D are side views illustrating rotor apparatuses and apparatuses for detecting an angular position of a rotor, according to embodiments.

FIG. 4 is a view illustrating a correspondence relationship between an identification layer and an angular position, in a rotor apparatus and an apparatus for detecting an angular position of a rotor, according to an embodiment.

FIG. 5 is a view illustrating temperature characteristics of an angular range identification structure, in a rotor apparatus and an apparatus for detecting an angular position of a rotor, according to an embodiment.

FIG. 6 is a view illustrating a process of generating rotation information in a rotor apparatus and an apparatus for detecting an angular position of a rotor, according to an embodiment.

FIGS. 7A and 7B are views illustrating an electronic device including a rotor apparatus and an apparatus for detecting an angular position of a rotor, according to an embodiment.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure. Hereinafter, while embodiments of the present disclosure will be described in detail with reference to the accompanying drawings, it is noted that examples are not limited to the same.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. As used herein “portion” of an element may include the whole element or less than the whole element.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of this disclosure. Further, although the examples described herein have a variety of configurations, other configurations are possible as will be apparent after an understanding of this disclosure.

Herein, it is noted that use of the term “may” with respect to an example, for example, as to what an example may include or implement, means that at least one example exists in which such a feature is included or implemented while all examples are not limited thereto.

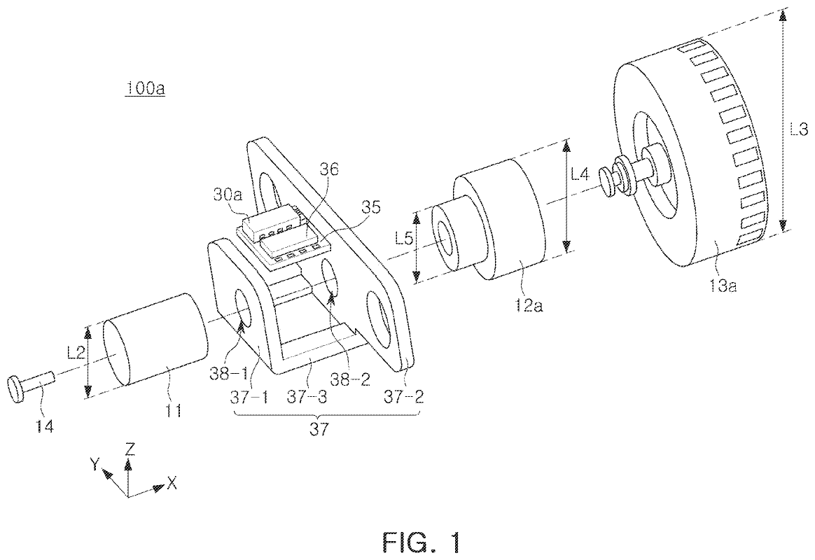

FIG. 1 is an exploded view illustrating a detailed form of a rotor apparatus and an apparatus for detecting an angular position of a rotor, according to an embodiment.

Referring to FIG. 1, a rotor apparatus and an apparatus for detecting an angular position of a rotor 100a may include, for example, a rotor 11, a rotating connector 12a, a rotating head 13a, a pin 14, an identification inductor 30a, a substrate 35, a processor 36, and a fixing member 37.

One end of the rotor 11 may be coupled to the rotating head 13a through the rotating connector 12a, and the other end of the rotor 11 may be coupled to the pin 14. A structure in which the rotor 11, the rotating connector 12a, the rotating head 13a, and the pin 14 are coupled to one another may rotate around a rotational axis (e.g., an X axis). For example, the rotor 11, the rotating connector 12a, the rotating head 13a, and the pin 14 may rotate together around the rotational axis (e.g., the X axis). For example, the rotor 11 may have a cylindrical shape or a polygonal column (e.g., an octagonal column) shape.

The rotating head 13a may be configured such that torque may be efficiently applied from an external entity. For example, the rotating head 13a may have a plurality of grooves configured such that a human hand does not slide while the hand is in contact with the rotating head 13a. For example, the rotating head 13a may have a diameter L3 greater than a diameter L2 of the rotor 11, such that a human hand can effectively exert force on the rotating head 13a. For example, the rotating head 13a may be a crown of a watch, but is not limited thereto.

For example, either one or both of the rotor 11 and the rotating head 13a may include a plastic material. Therefore, the apparatus 100a may be lightweight, such that the rotor 11 and the rotating head 13a may be rotated by the human hand.

The rotating connector 12a may be configured to efficiently rotate according to the torque applied to the rotating head 13a. For example, the rotating connector 12a may have a spindle structure, and may be coupled to the rotating head 13a by screw connection. For example, the rotating connector 12a may have a cylindrical shape in which a diameter L4 of one end of the rotating connector 12a is different from a diameter L5 of the other end of the rotating connector 12a.

The structure in which the rotor 11, the rotating connector 12a, the rotating head 13a, and the pin 14 are coupled to one another may be disposed on the fixing member 37. The fixing member 37 may be configured to be fixed to an electronic device.

For example, the fixing member 37 may have a structure in which a first part 37-1, a second part 37-2, and a third part 37-3 are coupled to one another. The first and second parts 37-1 and 37-2 may have first and second through-holes 38-1 and 38-2, respectively, and the third part 37-3 may be connected between the first and second parts 37-1 and 37-2 and may be configured to extend perpendicularly to the first and second parts 37-1 and 37-2.

The rotor 11 may be disposed to penetrate at least one of the first and second through-holes 38-1 and 38-2. Therefore, the rotor 11 may maintain a spacing distance from the identification inductor 30a during rotation and may stably rotate. Therefore, the rotor 11 may have longer lifespan.

The fixing member 37 may fix a positional relationship between the identification inductor 30a and the rotor 11. For example, the identification inductor 30a may be fixed on the substrate 35, and the substrate 35 may be fixed on the fixing member 37.

The substrate 35 may have a structure in which at least one wiring layer and at least one insulating layer are alternately stacked, such as a printed circuit board (PCB), and the identification inductor 30a may be electrically connected to the wiring layer of the substrate 35.

The processor 36 may be disposed on the substrate 35 and may be electrically connected to the identification inductor 30a through a wiring layer of the substrate 35. For example, the processor 36 may be implemented as an integrated circuit, and may be mounted on the upper surface of the substrate 35.

The processor 36 may generate an angular position value on the basis of inductance of the identification inductor 30a. For example, the processor 36 may output an output signal to the identification inductor 30a, and may receive an input signal based on the output signal and inductance of the identification inductor 30a. Since a resonant frequency of the output signal may be dependent on inductance of the identification inductor 30a, the processor 36 may recognize inductance of the identification inductor 30a by detecting the resonant frequency of the output signal, and may generate an angular position value corresponding to the inductance of the identification inductor 30a.

The identification inductor 30a may form magnetic flux according to the output signal received from the processor 36. The identification inductor 30a may be disposed to output magnetic flux towards the rotor 11. For example, the identification inductor 30a may have a coil shape, and may have a structure in which at least one coil layer and at least one insulation layer, each including a wound wire, are alternately stacked.

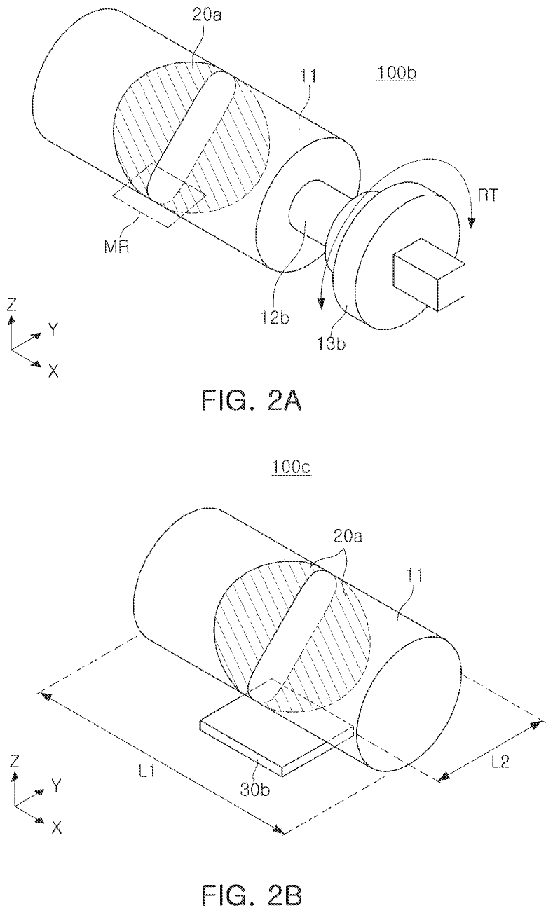

FIGS. 2A and 2B are perspective views illustrating a structure for detecting an angular position of a rotor, according to an embodiment.

Referring to FIG. 2A, a rotor apparatus and an apparatus for detecting an angular position of a rotor 100b, according to an embodiment, may include the rotor 11 and an angular position identification layer 20a.

The rotor 11 may be configured to rotate in a clockwise (RT) direction or a counterclockwise direction around a rotational axis (e.g., an X axis). Magnetic flux around the rotor 11 may pass through a magnetic flux region MR of a side surface of the rotor 11. An angular position of the magnetic flux region MR may be determined according to rotation of the rotor 11.

The angular position identification layer 20a may be disposed to surround the side surface of the rotor 11 and may have a width varying depending on the angular position of the rotor 11. For example, the angular position identification layer 20a may be plated on the side surface of the rotor 11, and may be inserted into the rotor 11 in the form of a ring in a state of being manufactured beforehand.

The magnetic flux passing through the magnetic flux region MR on the side surface of the rotor 11 may form an eddy current of the angular position identification layer 20a. Since a direction of the eddy current is similar to a direction of current of a coil, the eddy current may work as a parasitic inductor and may provide parasitic inductance.

The greater the diameter of the coil, the greater the inductance of the coil may be, and the greater the diameter of the region forming the eddy current, the greater the inductance according to the eddy current may be.

The greater the width of a portion corresponding to the magnetic flux region MR in the angular position identification layer 20a, the greater the diameter of the region forming the eddy current may be.

Since the width of the angular position identification layer 20a may vary according to the angular position of the rotor 11, the diameter of the region forming the eddy current formed on the angular position identification layer 20a may vary according to the angular position of the rotor 11. For example, the inductance according to the eddy current dependent on the magnetic flux passing through the magnetic flux region MR may vary according to the angular position of the rotor 11.

Therefore, the angular position identification layer 20a may provide inductance dependent on a degree of rotation of the rotor 11.

Precision and accuracy of the angular position identification of the rotor 11 may be higher as a rate of change of the inductance of the eddy current according to the change in width of the angular position identification layer 20a increases.

For example, the angular position identification layer 20a may include any one or any combination of any two or more of copper, silver, gold, and aluminum. Therefore, the angular position identification layer 20a may have high conductivity such that the angular position identification layer 20a may form a larger eddy current.

One end of the rotor 11 may be coupled to the rotating head 13b through the rotating connector 12b. The rotating head 13b may include a plastic material having a lighter weight, compared to the angular position identification layer 20a.

Referring to FIG. 2B, a rotor apparatus and an apparatus for detecting an angular position of a rotor 100c, according to an embodiment, may have a structure in which a rotating connector and a rotating head are not included.

An identification inductor 30b may be disposed to overlap an angular position identification layer 20a in a normal direction of a side surface of the rotor 11.

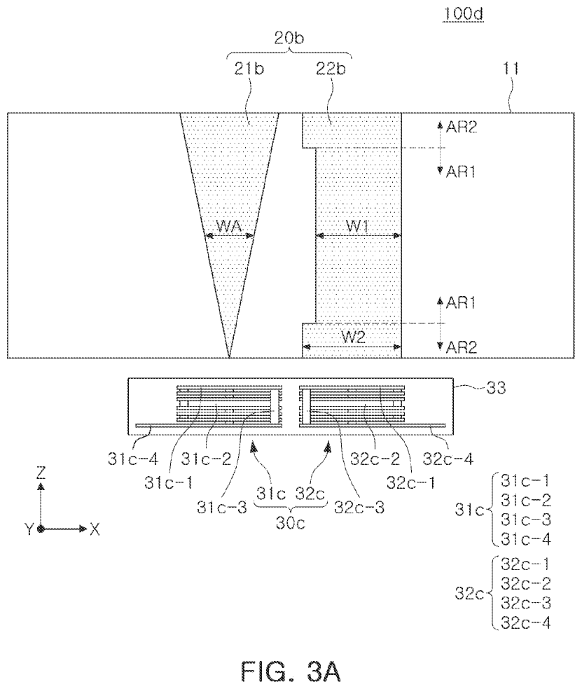

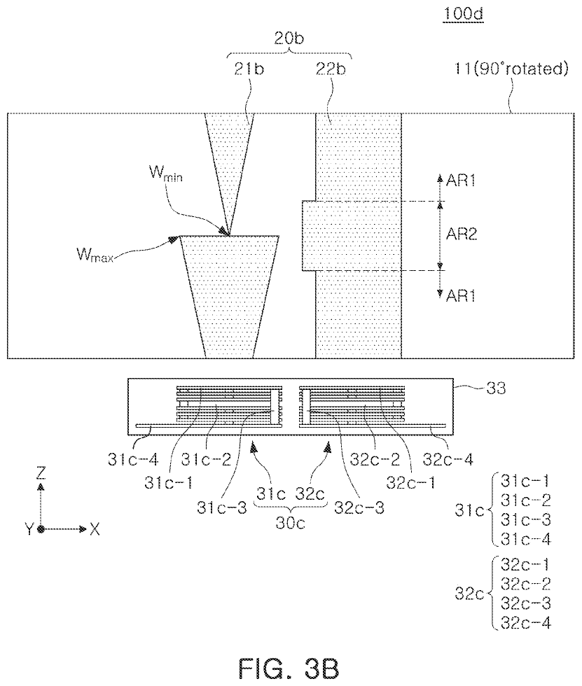

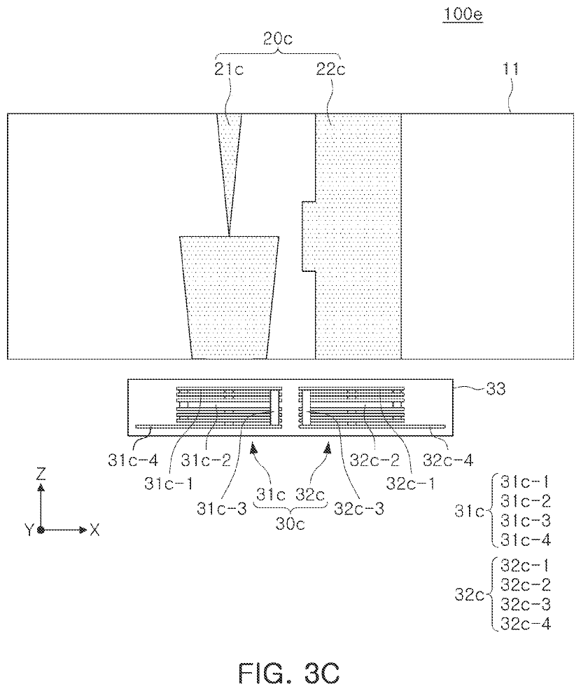

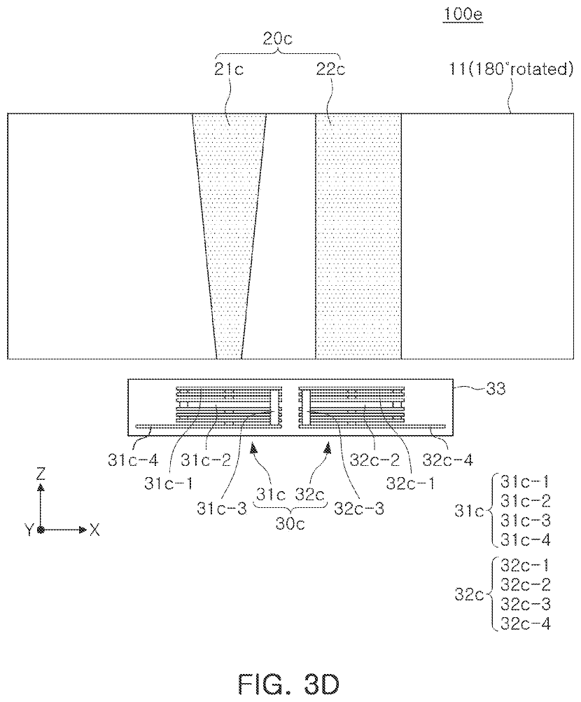

FIGS. 3A to 3D are side views illustrating rotor apparatuses and an apparatuses for detecting an angular position of a rotor, according to embodiments.

Referring to FIGS. 3A and 3B, a rotor apparatus, according to an embodiment, may include the rotor 11 and an identification layer 20b, and an apparatus for detecting an angular position of a rotor 100d, according to an embodiment, may include the rotor 11, the identification layer 20b, and an identification inductor 30c.

The rotor 11 may be configured to rotate around a rotational axis (e.g., an X axis). The orientation of the rotor 11 illustrated in FIG. 3A may be changed into the orientation illustrated in FIG. 3B by rotating 90 degrees in a clockwise or counterclockwise direction.

The identification layer 20b may include an angular position identification layer 21b and an angular range identification layer 22b, and may be disposed to surround the rotational axis of the rotor 11 and rotate according to rotation of the rotor 11. For example, the identification layer 20b may rotate according to rotation of the rotor 11 by being physically coupled to a side surface of the rotor 11.

The identification inductor 30c may include an angular position identification inductor 31c and an angular range identification inductor 32c, may be disposed to be adjacent to the identification layer 20b, to have inductance dependent on an eddy current formed in the identification layer 20b, and may be disposed to be spaced apart from the identification layer 20b.

For example, the angular position identification inductor 31c may have a stacked structure in which at least one first coil pattern 31c-1 and at least one first coil insulating layer 31c-2 are alternately stacked with each other, may include a first coil via 31c-3 vertically connected to the first coil pattern 31c-1, and may include a first lead-out portion 31c-4 electrically connected to the at least one first coil pattern 31c-1 to be led out to a surface of the angular position identification inductor 31c. For example, the angular range identification inductor 32c may have a stacked structure in which at least one second coil pattern 32c-1 and at least one second coil insulating layer 32c-2 are alternately stacked with each other, may include a second coil via 32c-3 vertically connected to the second coil pattern 32c-1, and may include a second lead-out portion 32c-4 electrically connected to the at least one second coil pattern 32c-1 to be led out to a surface of the angular range identification inductor 32c. For example, the angular position identification inductor 31c and the angular range identification inductor 32c may be implemented as a single inductor package 33.

The angular position identification layer 21b may have a width WA varying with angular positions of the rotor 11, and may be configured such that inductance of the angular position identification inductor 31c varies with angular positions of the rotor. Inductance may form resonance, together with constant capacitance, and resonant frequency may be dependent on the inductance. The larger the inductance is, the lower the resonant frequency may be, and the smaller the inductance is, the higher the resonant frequency may be. The resonant frequency may be used to detect the angular positions of the rotor 11.

The angular position identification layer 21b may have a minimum width Wₘᵢₙ and a maximum width W_{max.} The inductance of angular position identification inductor 31c may have the highest inductance when a portion corresponding to the minimum width Wₘᵢₙ in the angular position identification layer 21b is closest to the angular position identification inductor 31c, and may have the lowest inductance when a portion corresponding to the maximum width Wₘₐₓ in the angular position identification layer 21b is closest to the angular position identification inductor 31c.

The width WA between the minimum width Wₘᵢₙ and the maximum width Wₘₐₓ of the angular position identification layer 21b may change linearly according to rotation of the rotor 11. Therefore, efficiency and accuracy of detecting angular positions of the rotor 11 may increase.

As a length between the minimum width Wₘᵢₙ and the maximum width Wₘₐₓ of the angular position identification layer 21b increases, a relationship between the width WA of the angular position identification layer 21b and an angular position of the rotor 11 may be closer to a one-on-one relationship. Therefore, efficiency and accuracy of detecting angular positions of the rotor 11 may further increase.

Therefore, a clockwise length and a counterclockwise length between a point having the maximum width Wₘₐₓ and a point having the minimum width Wₘᵢₙ of the angular position identification layer 21b may be different from each other. One of the clockwise length and the counterclockwise length between the point having the maximum width Wₘₐₓ and the point having the minimum width Wₘᵢₙ may be relatively long, while the other thereof may be relatively short. For example, one of the clockwise length and the counterclockwise length may be close to a circumference of the rotor 11, and the other thereof may be close to zero.

Therefore, a width within the shorter one of the clockwise length and the counterclockwise length between the minimum width Wₘᵢₙ and the maximum width Wₘₐₓ of the angular position identification layer 21b may have a lower correlation characteristic with respect to the angular position of the rotor 11, compared to the width WA within a longer one of the clockwise length and the counterclockwise length. Therefore, it may be relatively inefficient for the width within the shorter one of the clockwise length and the counterclockwise length to be used for detecting the angular position of the rotor 11. The inductance of the angular position identification inductor 31c may be a parameter that does not reflect whether the angular position of the rotor 11 is disposed in the longest or shortest one of the clockwise length and the counterclockwise length between the minimum width Wₘᵢₙ and the maximum width Wₘₐₓ

The angular range identification layer 22b may have a shape different from a shape of the angular position identification layer 21b, and may have a greatest changing width in a portion corresponding to both sides of an angular position range AR2, among a plurality of different angular position ranges AR1 and AR2 of the rotor 11, in which an angular position corresponding to a point having the largest change in width of the angular position identification layer 21b is located(e.g., within the shorter one of the clockwise length and counterclockwise length between the minimum width Wₘᵢₙ and the maximum width Wₘₐₓ of the angular position identification layer 21b). For example, the greatest changing width may be implemented by having a boundary line of the angular range identification layer 22b having an angular shape, and a change rate of width of the angular shape may be infinite.

Alternatively, the angular range identification layer 22b may be configured such that an overall width W2 of a portion corresponding to an angular position range AR2, among a plurality of different angular position ranges AR1 and AR2 of the rotor 11, in which an angular position corresponding to a point reversing a width change direction of the angular position identification layer 21b is located, is different from an overall width W1 of a remaining portion (e.g., within the shorter one of the clockwise length and counterclockwise length between the minimum width Wₘᵢₙ and the maximum width Wₘₐₓ of the angular position identification layer 21b). In this case, the overall width may be an average width of a corresponding angular position range, and may be a value obtained by integrating a width by a length of the corresponding angular position range.

Alternatively, the angular range identification layer 22b may be configured such that overall inductance of the angular range identification inductor 32c in an angular position range AR2, among a plurality of different angular position ranges AR1 and AR2 of the rotor 11, in which an angular position corresponding to a point reversing an inductance change direction of the angular position identification inductor 31c is located, is different from overall inductance of the angular range identification inductor 32c in remaining angular position ranges (AR1) among the plurality of different angular position ranges AR1 and AR2 (e.g., within the shorter one of the clockwise length and counterclockwise length between the minimum width Wₘᵢₙ and the maximum width Wₘₐₓ of the angular position identification layer 21b).

Therefore, the inductance of the angular range identification inductor 32c may be a parameter reflecting whether the angular position of the rotor 11 is located in the longest or shortest one of the clockwise length and the counterclockwise length between the minimum width Wₘᵢₙ and the maximum width Wₘₐₓ, and may contribute to improving accuracy of detecting the angular position of the rotor 11 based on the inductance of the angular position identification inductor 31c.

For example, a widest portion of the angular range identification layer 22b may have a constant width W2 between points of the angular range identification layer 22b having the largest change in width (e.g., angled points in the boundary line). Therefore, the inductance of the angular range identification inductor 32c may be used as a reference value for the inductance of the angular position identification inductor 31c, and may be thus used precisely in a process of further improving accuracy of the inductance of the angular position identification inductor 31c (e.g., a value correction process, a temperature correction process, or the like).

For example, a clockwise length and a counterclockwise length between a plurality of points having the largest change in width (e.g., angled points in the boundary line) in the angular range identification layer 22b may be different from each other. Therefore, the inductance of the angular range identification inductor 32c may be more efficiently used as a reference value for the inductance of the angular position identification inductor 31c.

For example, a change in width of the plurality of points having the largest change in width (e.g., angled points in the boundary line) in the angular range identification layer 22b may be greater than a change in width of a portion in which a width changes linearly, except for a point having the largest change in width, of the angular position identification layer 21b (e.g., within the shorter one of the clockwise length and counterclockwise length between the minimum width Wₘᵢₙ and the maximum width Wₘₐₓ of the angular position identification layer 21b). Therefore, information on which angular position range among the plurality of angular position ranges AR1 and AR2 corresponds to an angular position of the rotor 11 may be obtained more stably based on inductance of the angular range identification inductor 32c.

Referring to FIGS. 3C and 3D, a rotor apparatus and an apparatus for detecting an angular position of a rotor 100e, according to an embodiment, may include an identification layer 20c. The identification layer 20c may include an angular position identification layer 21c and an angular range identification layer 22c.

The angular position identification layer 21c may have a width corresponding to an angular position one-to-one in a range of one turn (360 degrees) of the rotor 11. Therefore, efficiency and accuracy of detecting an angular position of the rotor 11 may further increase.

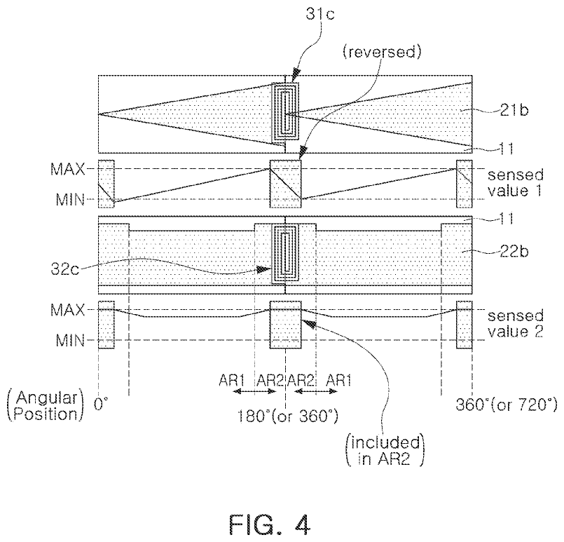

FIG. 4 is a view illustrating a correspondence relationship between an identification layer and an angular position, in a rotor apparatus and an apparatus for detecting an angular position of a rotor, according to an embodiment.

Referring to FIG. 4, a resonant frequency (sensed value 1) dependent on inductance of an angular position identification inductor 31c may have a steeper slope when an angular position of the rotor 11 is located in a second angular position range AR2, and a resonant frequency (sensed value 2) dependent on inductance of an angular range identification inductor 32c may have a higher value when an angular position of the rotor 11 is located in the second angular position range AR2.

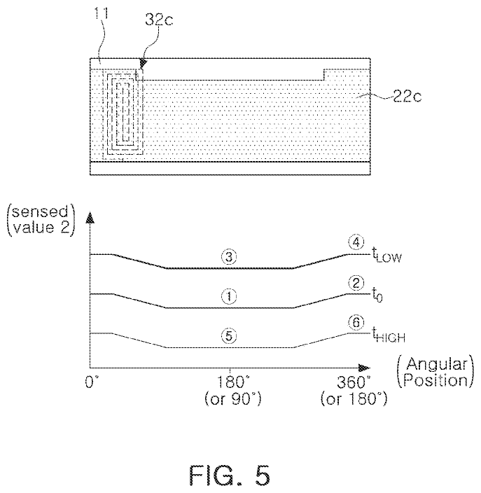

FIG. 5 is a view illustrating temperature characteristics of an angular range identification structure in a rotor apparatus and an apparatus for detecting an angular position of a rotor, according to an embodiment.

Referring to FIG. 5, a resonant frequency (sensed value 2) dependent on inductance of an angular range identification inductor 32c may be relatively high at a temperature t_{LOW} lower than a reference temperature t₀, and may be relatively low at a temperature t_{HIGH} higher than the reference temperature t₀.

Since inductance of an angular position identification inductor may also vary according to a temperature, the inductance of the angular position identification inductor may be corrected based on the inductance of the angular range identification inductor 32c.

For example, the inductance of the angular position identification inductor may be corrected in a direction in which the resonant frequency (sensed value 2) dependent on the inductance of the angular range identification inductor 32c is closer to that at the reference temperature t₀, and may be corrected until it becomes equal to that at the reference temperature t₀.

Due to an angular range identification layer 22c, resonant frequencies \hat{1}, \hat{3} and \hat{5} when an angular position of the rotor falls within a first angular position range may be different from resonant frequencies \hat{2}, \hat{4} and \hat{6} when an angular position of the rotor falls within a second angular position range.

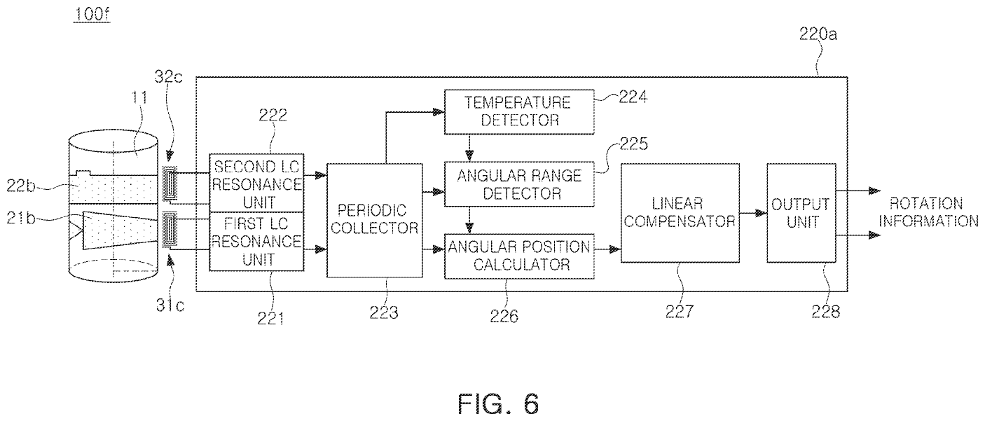

FIG. 6 is a view illustrating a process of generating rotation information, in a rotor apparatus and an apparatus for detecting an angular position of a rotor, according to an embodiment.

Referring to FIG. 6, a rotor apparatus and an apparatus for detecting an angular position of a rotor 100f, according to an embodiment, may further include a processor 220a. The processor 220a may include any one or any combination of any two or more of a first LC resonance unit 221, a second LC resonance unit 222, a periodic collector 223, a temperature detector 224, an angular range detector 225, an angular position calculator 226, a linear compensator 227, and an output unit (or outputter) 228. The processor 220a may include at least one of an analog circuit (e.g., an analog-to-digital converter, a buffer) or a digital processor (e.g., a CPU).

The first LC resonance unit 221 may include a first capacitor having first constant capacitance, and may thus generate resonance together with an angular position identification inductor 31c.

The second LC resonance unit 222 may include a second capacitor having second constant capacitance, and may thus generate resonance together with an angular range identification inductor 32c.

The periodic collector 223 may periodically collect a first resonant frequency of the first LC resonance unit 221 and a second resonant frequency of the second LC resonance unit 222. For example, the periodic collector 223 may apply a current or a voltage to the first and second LC resonators 221 and 222, may sense the voltage or the current, and may periodically control the collection of the first and second resonance frequencies by a sample-hold manner.

The temperature detector 224 may detect a temperature based on the second resonant frequency of the second LC resonance unit 222, or may detect a temperature based on detection of a temperature sensor in the processor 220a.

The angular range detector 225 may generate information on which angular position range among a plurality of angular position ranges includes an angular position of the rotor 11, based on the second resonant frequency of the second LC resonant unit 222.

The angular position calculator 226 may detect the angular position of the rotor 11, based on the first resonant frequency of the first LC resonance unit 221.

For example, the angular position calculator 226 may apply the first resonant frequency of the first LC resonance unit 221 to one operation logic selected based on information generated by the angular range detector 225, among a plurality of operation logics, to generate an angular position value. The plurality of operation logics may be stored in the processor 220a or in a memory electrically connected to the processor 220a. For example, a first operation logic may be based on a first polynomial equation and/or a first look-up table, and second operation logic may be based on a second polynomial equation and/or a second look-up table.

For example, the angular position calculator 226 may correct the first resonant frequency of the first LC resonance unit 221 based on information generated by the angular range detector 225, or correct an angular position value based on the first resonant frequency.

For example, the angular position calculator 226 may apply the first resonance of the first LC resonance unit 221 in a look-up table selected based on information generated by the angular range detector 225 or determined whether to be used according to the information generated by the angular range detector 225, to generate an angular position value. The look-up table and/or selectable look-up tables may be stored in the processor 220a or in a memory electrically connected to the processor 220a.

For example, the angular position calculator 226 may generate an angular position value based on the first resonant frequency of the first LC resonance unit 221, but may correct the angular position value based on information generated by the angular range detector 225 and/or information generated by the temperature detector 224.

Therefore, the rotor apparatus and an apparatus for detecting an angular position of a rotor 100f may more efficiently and accurately detect an angular position value of the rotor 11.

The linear compensator 227 may correct an output value of the angular position calculator 226 such that the output value of the angular position calculator 226 changes more linearly according to the angular position change of the rotor 11.

For example, the linear compensator 227 may generate corrected angular position values from the first resonant frequency of the first LC resonance unit 221, based on one correction logic selected based on inductance of the angular range detector 225, among a plurality of correction logics. For example, a first correction logic may be based on a look-up table, and a second correction logic may be based on a polynomial equation.

The output unit 228 may output rotation information (e.g., an angular position of the rotor) based on the output value of the linear compensator 227.

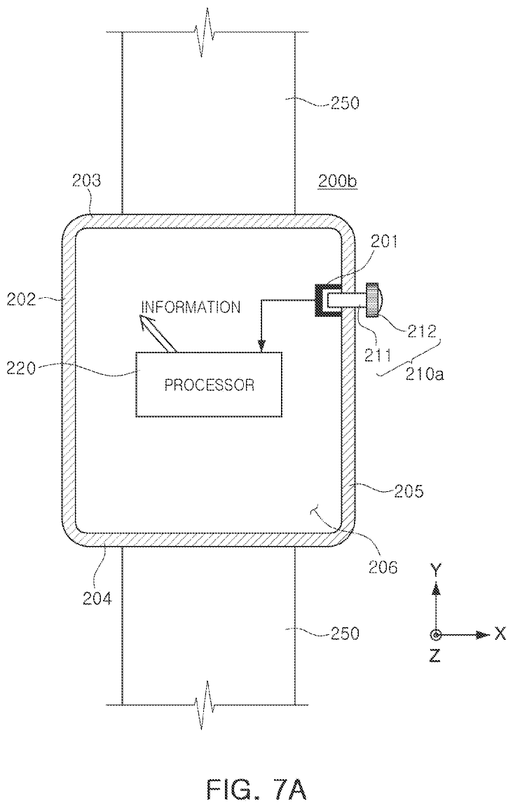

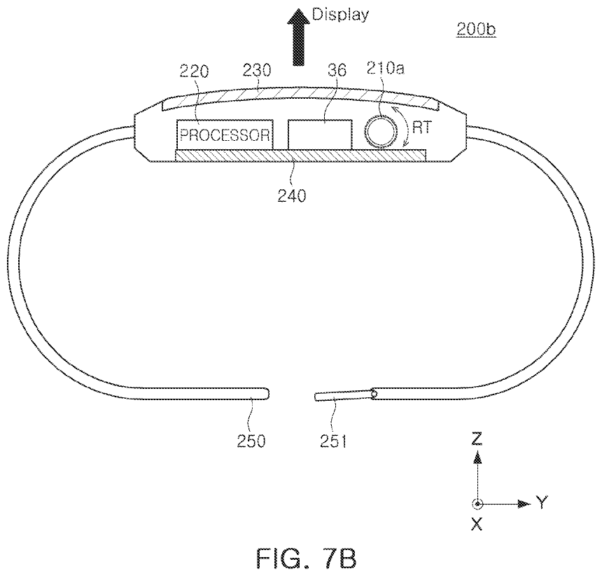

FIGS. 7A and 7B are views illustrating an electronic device including a rotor apparatus and an apparatus for detecting an angular position of a rotor, according to an embodiment.

Referring to FIG. 7A, an electronic device 200b may include a main body including at least two among a first surface 205, a second surface 202, a third surface 203, and a fourth surface 204.

For example, the electronic device 200b may be a smart watch, a smart phone, a personal digital assistant, a digital video camera, a digital still camera, a network system, a computer, a monitor, a tablet, a laptop, a netbook, a television, a video game, an automotive device, or the like, but is not limited to such examples.

The electronic device 200b may include a processor 220, may include a storage element for storing information, such as a memory or a storage, and may include a communication element for remotely transmitting and receiving information, such as a communication modem or an antenna.

The processor 220 may be disposed in an internal space 206 of the main body. For example, the processor 220 may include a central processing unit (CPU), a graphic processing unit (GPU), a microprocessor, an application specific integrated circuit (ASIC), field programmable gate arrays (FPGA), or the like, and may have multiple cores. For example, the processor 220 may input/output information for the storage element or the communication element.

The processor 220 may arc-tangent process a value including a denominator variable corresponding to one inductance of first and second inductors in a rotor apparatus and an apparatus for detecting an angular position of a rotor 210a and a numerator variable corresponding to the other inductance of the first and second inductors, thereby generating an angular position value. Therefore, the electronic device 200b may efficiently detect angular position information of the rotor apparatus 210a.

A rotor apparatus and an apparatus for detecting an angular position of a rotor 210a, according to an embodiment, may include a rotor 211 and a rotating head 212, and may be disposed on the first surface 205 of the main body.

A housing 201 may surround at least a portion of the rotor apparatus and the apparatus for detecting an angular position of a rotor 210a. The housing 201 may be coupled to the first surface 205 of the main body. For example, the housing 201 and the main body may be formed of an insulating material such as plastic.

The generated angular position value may be transmitted to the processor 220. For example, the processor 220 may generate information based on the received angular position value, may transmit the generated information to the storage element or the communication element, and may control a display member 230 (FIG. 7B) to output display information in the Z direction on the basis of the generated information.

Referring to FIGS. 7A and 7B, the electronic device 200b may be connected to any one or any combination of any two or more of the first, second, third, and fourth surfaces 205, 202, 203, and 204 of the main body, and may further include a strap 250 that is more flexible than the main body.

Therefore, since the strap 250 may be disposed over a user (or clothing of a user) of the electronic device 200b, the user may use the electronic device 200b conveniently. For example, one end and the other end of the strap 250 may be coupled to each other through a coupling portion 251.

Referring to FIG. 7B, the electronic device 200b may include a display member 230 and an electronic device substrate 240, and may further include the processor 36.

The display member 230 may output display information in a normal direction (e.g., a Z direction) of the display member 230, different from a normal direction (e.g., an X direction and/or a Y direction) of the first, second, third and fourth surfaces 205, 202, 203, and 204 of the main body. The normal direction of the display member 230 and the normal direction of the display surface of the main body of the electronic device 200b may be the same.

At least a portion of the display information output by the display member 230 may be based on information generated by the processor 220. For example, the processor 220 may transmit display information based on the generated information to the display member 230.

For example, the display member 230 may have a structure in which a plurality of display cells are two-dimensionally arranged, and may receive a plurality of control signals based on operation information of the electronic device from the processor 220 or a separate processor. The plurality of display cells may be configured such that whether to display and/or a color may be determined on the basis of a plurality of control signals. For example, the display member 230 may further include a touch screen panel, and may be implemented using a relatively flexible material such as an OLED.

The electronic device substrate 240 may provide a dispositional space for the processor 220 and may provide an information transmission path between the processor 220 and the display member 230. For example, the electronic device substrate 240 may be implemented as a printed circuit board (PCB).

The processor 220 may be implemented similarly to the processor illustrated in FIGS. 1 and 6, and may be separated from a rotor apparatus and an apparatus for detecting an angular position of a rotor 210a and disposed on the substrate 240, differently from the processor illustrated in FIG. 1.

According to embodiments disclosed herein, efficiency and/or accuracy of detecting an angular position of a rotor may be improved.

Additionally, according to embodiments disclosed herein, linearity for detecting an angular position may efficiently increase, and a more robust angular position value may be generated for an external environment (e.g., a temperature).

The processors 36, 220, and 220a, the first LC resonance unit 221, the second LC resonance unit 222, the periodic collector 223, the temperature detector 224, the angular range detector 225, the angular position calculator 226, the linear compensator 227, and the output unit 228 in FIGS. 1 to 7B that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1 to 7B that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD−Rs, CD+Rs, CD−RWs, CD+RWs, DVD-ROMs, DVD−Rs, DVD+Rs, DVD−RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A rotor apparatus, comprising:
a rotor configured to rotate around a rotational axis;
an angular position identification layer disposed to surround the rotational axis and configured to rotate according to rotation of the rotor, and having a width varying with angular positions of the rotor; and
an angular range identification layer disposed to surround the rotational axis, configured to rotate according to the rotation of the rotor, having a shape different from a shape of the angular position identification layer, and configured such that an overall width of a portion of the angular range identification layer corresponding to an angular position range, among a plurality of different angular position ranges of the rotor, in which an angular position corresponding to a point having the largest change in width of the angular position identification layer is located, is different from an overall width of a remaining portion of the angular range identification layer.

2. The rotor apparatus of claim 1, wherein the angular position identification layer and the angular range identification layer comprise any one or any combination of any two or more of copper, silver, gold, or aluminum as a material, different from a material of the rotor, respectively.

3. The rotor apparatus of claim 1, wherein the angular range identification layer has a width changing in a highest ratio in a portion corresponding to both sides of an angular position range, among the plurality of different angular position ranges, to which the angular position corresponding to the point having the largest change in width of the angular position identification layer belongs.

4. The rotor apparatus of claim 1, wherein a widest portion of the angular range identification layer has a constant width between points of the angular range identification layer having the largest change in width.

5. The rotor apparatus of claim 1, wherein the angular position identification layer has a width changing linearly, except for the point having the largest change in width.

6. The rotor apparatus of claim 5, wherein a change in width of a plurality of points having the largest change in width in the angular range identification layer is greater than a change in width of a portion of the angular range identification layer in which a width changes linearly, except for the point having the largest change in width in the angular position identification layer.

7. The rotor apparatus of claim 1, wherein the angular position identification layer has a width corresponding one-on-one to an angular position in one turn range of the rotor.

8. The rotor apparatus of claim 1, wherein a clockwise length and a counterclockwise length between a point having a maximum width and a point having a minimum width in the angular position identification layer are different from each other.

9. The rotor apparatus of claim 8, wherein a clockwise length and a counterclockwise length between one point and another point among a plurality of points having the largest change in width in the angular range identification layer are different from each other.

10. A rotor apparatus, comprising:
a rotor configured to rotate around a rotational axis;
an angular position identification layer disposed to surround the rotational axis and configured to rotate according to rotation of the rotor, and having a width varying with angular positions of the rotor; and
an angular range identification layer disposed to surround the rotational axis, configured to rotate according to the rotation of the rotor, having a shape different from a shape of the angular position identification layer, and configured such that an overall width of a portion of the angular range identification layer corresponding to an angular position range, among a plurality of different angular position ranges of the rotor, in which an angular position corresponding to a point reversing a width change direction of the angular position identification layer is located, is different from an overall width of a remaining portion of the angular range identification layer.

11. The rotor apparatus of claim 10, wherein a clockwise length and a counterclockwise length between a point having a maximum width and a point having a minimum width in the angular position identification layer are different from each other.

12. The rotor apparatus of claim 11, wherein a clockwise length and a counterclockwise length between a plurality of points having the largest change in width in the angular range identification layer are different from each other.

13. The rotor apparatus of claim 12, wherein a widest portion of the angular range identification layer has a constant width between points of the angular range identification layer having the largest change in width.

14. The rotor apparatus of claim 11, wherein the angular position identification layer has a width changing linearly.

15. An apparatus for detecting an angular position of a rotor, comprising:
an angular position identification inductor;
an angular range identification inductor;
a rotor configured to rotate around a rotational axis;
an angular position identification layer disposed to surround the rotational axis and configured to rotate according to rotation of the rotor, and configured to change an inductance of the angular position identification inductor according to angular positions of the rotor; and
an angular range identification layer disposed to surround the rotational axis and configured to rotate according to the rotation of the rotor, and configured such that overall inductance of the angular range identification inductor in an angular position range, among a plurality of different angular position ranges of the rotor, in which an angular position corresponding to a point reversing an inductance change direction of the angular position identification inductor is located, is different from overall inductance of the angular range identification inductor in a remaining angular position range among the plurality of different angular position ranges.

16. The apparatus of claim 15, further comprising a processor configured to generate an angular position value, based on one operation logic selected based on the inductance of the angular range identification inductor, among a plurality of operation logics, and based on the inductance of the angular position identification inductor.

17. The apparatus of claim 16, wherein the processor is further configured to correct the angular position value or the inductance of the angular position identification inductor, based on the inductance of the angular range identification inductor.

18. The apparatus of claim 15, further comprising a processor configured to generate an angular position value, based on a look-up table selected based on the inductance of the angular range identification inductor or determined whether to be used according to the inductance of the angular range identification inductor and the inductance of the angular position identification inductor.

19. The apparatus of claim 15, further comprising a processor configured to generate an angular position value based on the inductance of the angular position identification inductor, and correct the angular position value based on the inductance of the angular range identification inductor.

20. The apparatus of claim 15, further comprising a processor configured to generate an angular position value corrected from the inductance of the angular position identification inductor, based on one correction logic selected based on the inductance of the angular range identification inductor, among a plurality of correction logics.
